(19) United States
(12) Patent Application Publication
(10) Pub. No.: US 2026/0304899 A1
(43) Pub. Date: Oct. 1, 2026

(54) SEMICONDUCTOR DEVICE AND METHOD OF MAKING THE SAME

(71) Applicant: Taiwan Semiconductor Manufacturing Company, LTD., Hsinchu (TW)

(72) Inventors: Tzu Jung Tien, Hsinchu (TW); Cheung Cheng, Hsinchu (TW)

(21) Appl. No.: 19/286,419

(22) Filed: Jul. 31, 2025

Related U.S. Application Data
(60) Provisional application No. 63/781,423, filed on Apr. 1, 2025.

(51) Int. Cl. H10D 64/27; H10D 64/01

(52) U.S. Cl. CPC H10D 64/518; H10D 64/01

(57) ABSTRACT

The gate structure of a planar transistor has two opposite sides that pass across an active region between two source/drain regions. The two opposite sides are not parallel to each other. As a result, the channel length between the two source/drain regions is not constant across the width of the gate structure. Put another way, multiple channels with different lengths are present between the two source/drain regions. This structure results in high subthreshold swing performance, which manifests as faster transition between the on/off states of the transistor.

### CROSS-REFERENCE TO RELATED APPLICATIONS

This application claims priority to U.S. Provisional Patent Application Ser. No. 63/781,423, filed on Apr. 1, 2025, which is incorporated by reference in its entirety.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

An integrated circuit is made of large numbers of transistors. A field-effect transistor is generally composed of a substrate on which an electrically conductive gate structure controls the flow of current between a source electrode and a drain electrode. An electrically insulating gate dielectric layer separates the gate structure from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view showing a first example embodiment of a transistor having multiple different channel lengths due to different gate dimensions, in accordance with some embodiments of the present disclosure. FIG. 1B is a Y-axis cross-sectional view along line B-B of FIG. 1A. FIG. 1C is a Y-axis cross-sectional view along line C-C of FIG. 1A. FIG. 1D is an X-axis cross-sectional view along line D-D of FIG. 1A. FIG. 1E is an X-axis cross-sectional view along line E-E of FIG. 1A.

FIG. 2 is a flow chart illustrating a first method for forming a transistor, in accordance with some embodiments. Various steps of this method are shown in FIGS. 3A-4B.

FIG. 3A is a plan view of the substrate after forming one or more isolation regions to define an active region. FIG. 3B is an X-axis cross-sectional view along line B-B of FIG. 3A.

FIG. 4A is a plan view of the substrate after formation of a gate dielectric layer. FIG. 4B is an X-axis cross-sectional view along line B-B of FIG. 4A.

FIG. 5 is a graph of drain current vs. gate voltage. The y-axis is logarithmic, while the x-axis is linear. This graph compares a transistor where the channel length is constant across a width of the active region against a transistor where the channel length has multiple different values across the width of the active region.

FIG. 6A is a plan view showing a second example embodiment of a transistor, in accordance with some embodiments of the present disclosure. Here, one side of the gate structure is a curved surface.

FIG. 6B is a plan view showing a third example embodiment of a transistor, in accordance with some embodiments of the present disclosure. Here, one side of the gate structure has a stepped structure that provides varying channel lengths.

FIG. 7A is a plan view showing a first example embodiment of two transistors with two non-rectangular polygonal gate structures having different dimensions that share a common S/D region.

FIG. 7B is a plan view showing a second example embodiment of two transistors with two non-rectangular polygonal gate structures having different dimensions that share a common S/D region.

FIG. 8A is a plan view showing one possible variation of the transistor, in accordance with some embodiments of the present disclosure. FIG. 8B is an X-axis cross-sectional view along line B-B of FIG. 8A. Here, the thickness of the gate dielectric layer varies in different regions extending between the two S/D regions.

FIG. 9 is a flow chart illustrating different methods for forming a transistor with a gate dielectric layer as illustrated in FIGS. 8A-8B, in accordance with some embodiments. Various steps of this method are shown in FIGS. 10A-15B.

FIG. 10A is a plan view of the substrate after deposition of a first gate dielectric sublayer across three regions. FIG. 10B is an X-axis cross-sectional view along line B-B of FIG. 10A.

FIG. 11A is a plan view of the substrate after removal of the first gate dielectric sublayer from the second and third regions. FIG. 11B is an X-axis cross-sectional view along line B-B of FIG. 11A.

FIG. 12A is a plan view of the substrate after forming a second gate dielectric sublayer across the first and second regions. FIG. 12B is an X-axis cross-sectional view along line B-B of FIG. 10A.

FIG. 13A is a plan view of the substrate after forming a third gate dielectric sublayer across the three regions. FIG. 13B is an X-axis cross-sectional view along line B-B of FIG. 13A.

FIG. 14A is a plan view of the substrate after the gate structure has been formed, and after the gate structure and dielectric structure are patterned to have non-parallel sides. FIG. 14B is an X-axis cross-sectional view along line B-B of FIG. 14A.

FIG. 15A is an X-axis cross-sectional view of the substrate after an intermediate gate dielectric layer has been formed, and a mask has been applied to permit etching and partial removal of the thickness of the intermediate gate dielectric layer in the second region.

FIG. 15B is an X-axis cross-sectional view of the substrate after the intermediate gate dielectric layer has also been etched in the third region to obtain a gate dielectric layer with different thicknesses.

FIG. 16A is a plan view showing another possible variation of the transistor, in accordance with some embodiments of the present disclosure. FIG. 16B is an X-axis cross-sectional view along line B-B of FIG. 16A. Here, the dielectric constant of the gate dielectric layer varies in different regions extending between the two S/D regions.

FIG. 17 is a flow chart illustrating different methods for forming a transistor with a gate dielectric layer as illustrated in FIGS. 16A-16B, in accordance with some embodiments.

FIG. 18A is a plan view showing another possible variation of the transistor, in accordance with some embodiments of the present disclosure. FIG. 18B is an X-axis cross-sectional view along line B-B of FIG. 18A. Here, the work function of the gate structure varies in different regions extending between the two S/D regions.

FIG. 19 is a flow chart illustrating different methods for forming the transistor with a gate structure as illustrated in FIGS. 18A-18B, in accordance with some embodiments.

FIG. 20A is a plan view showing another example embodiment of a transistor, in accordance with some embodiments of the present disclosure. FIG. 20B is a Y-axis cross-sectional view along line B-B of FIG. 20A. FIG. 20C is a Y-axis cross-sectional view along line C-C of FIG. 20A. Here, a first dielectric sidewall and/or a second dielectric sidewall are also used to change the channel length across the width of the active region between the S/D regions.

FIG. 21 is a plan view showing another example embodiment of a transistor, in accordance with some embodiments of the present disclosure. Here, the first dielectric sidewall and/or second dielectric sidewall have a non-rectangular shape for changing the channel length across the width of the active region between the S/D regions.

FIG. 22 is a flow chart illustrating different methods for forming the transistor with a gate structure as illustrated in FIGS. 20A-20B and FIG. 21, in accordance with some embodiments.

FIGS. 23A-23C are plan views of different embodiments of a transistor, where one or more gate vias are placed over the active region. Their number, position, size, and/or bias may be controlled to change the electric field applied by the gate structure so as to further adjust the current flow between the two S/D regions.

FIG. 24 is a flow chart illustrating a method for forming a semiconductor package, in accordance with some embodiments. Various steps of this method are shown in FIG. 25.

FIG. 25 is a Y-axis cross-sectional view of the substrate along line B-B of FIG. 1A, after the transistor has been encapsulated in a first insulating layer, vias have been formed, a second insulating layer has been applied over a first insulating layer, and pads are formed in the second insulating layer to form a source terminal, a drain terminal, and a gate terminal, to form a semiconductor package.

FIG. 26 is a flow chart illustrating a method for using a transistor, in accordance with some embodiments of the present disclosure.

FIG. 27A is a circuit diagram showing a first example embodiment of a pixel driver circuit in which the transistors of the present disclosure can be used. This circuit diagram is a 7T2C circuit.

FIG. 27B is a circuit diagram showing a second example embodiment of a pixel driver circuit in which the transistors of the present disclosure can be used. This circuit diagram is an 8T2C circuit.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 20% of the indicated number.

The present disclosure refers to the “width” as being in the direction of the X-axis and the “length” as being in the direction of the Y-axis. This correspondence is arbitrary. The term “length” should not be construed as always having a greater value than the “width”.

The term “parallel” is used herein generally to describe two edges or surfaces that run in the same direction. This term should not be interpreted in a strict mathematical way requiring the two edges or surfaces to never intersect with each other.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

Several flow charts illustrating methods are included and discussed herein. While the method steps are discussed in terms of forming a single transistor, such discussion should also be broadly construed as applying to the concurrent formation of multiple transistors. Other structures may also be concurrently formed. It is noted that not all steps described in each flow chart are required, and not all method steps are described in each flow chart.

The present disclosure relates to various methods and structures which are particularly useful in improving the performance of high-voltage and medium-voltage transistors. The subthreshold swing is the change in gate voltage needed to change the drain current by one decade (i.e. factor of 10) in the subthreshold region. In the present disclosure, a specified gate structure is used to improve the performance. The gate structure has multiple dimensions so as to create multiple or many different channel lengths between source/drain regions. A composite gate length (Lg) is used to obtain high subthreshold swing. This can also be combined with different gate dielectric layer thicknesses, and/or different gate dielectric layer dielectric constants, and/or different gate structure work functions, as will be described herein. High subthreshold swing can manifest as faster transition between the on (high current) state and the off (low current) states of the transistor. This can result in robust devices, smaller devices, and/or devices with higher operational frequencies.

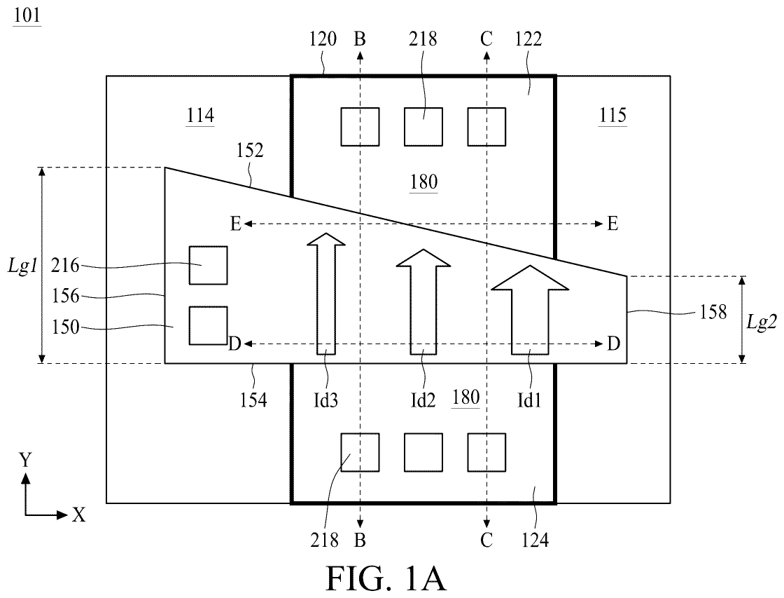

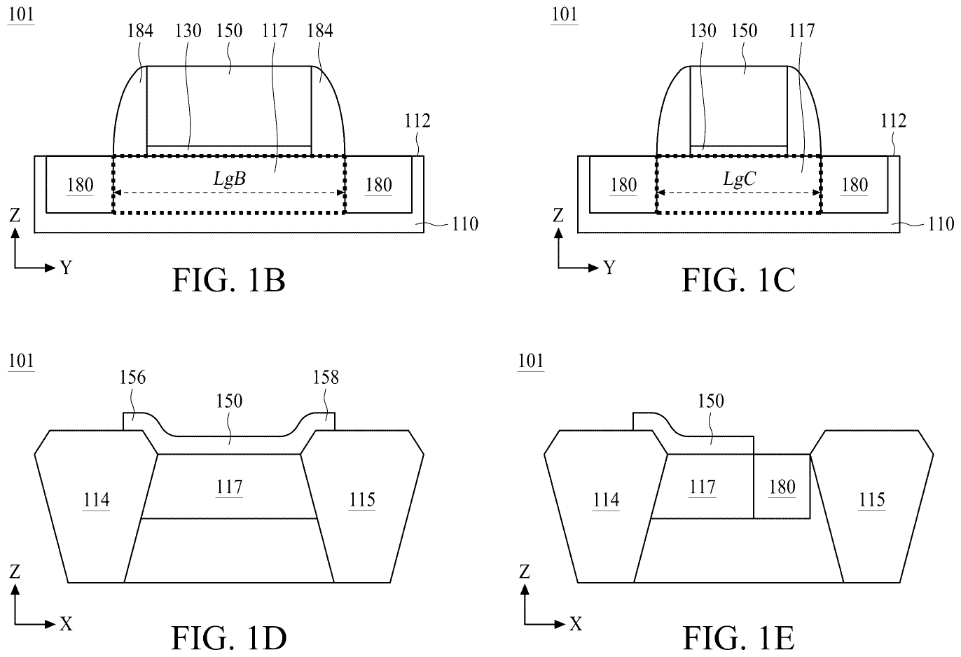

FIG. 1A is a plan view showing a first example embodiment of a transistor 101 having multiple channel lengths, in accordance with some embodiments of the present disclosure, and illustrating some features. FIG. 1B is a Y-axis cross-sectional view along line B-B of FIG. 1A. FIG. 1C is a Y-axis cross-sectional view along line C-C of FIG. 1A. FIG. 1D is an X-axis cross-sectional view along line D-D of FIG. 1A. FIG. 1E is an X-axis cross-sectional view along line E-E of FIG. 1A.

Referring to the figures together, the transistor 101 is formed on a substrate 110. Two isolation regions 114, 115 are present that extend along the Y-axis, which may be, for example, shallow trench isolation (STI) regions or deep trench isolation (DTI) regions. The area between them is defined as an active region 120. It is noted that there may also be isolation regions in the X-axis (not illustrated), so that the active region is surrounded on all sides. The active region generally has a rectangular shape. As illustrated in FIG. 1B, a channel 117 is present between the isolation regions.

As better seen in FIG. 1B and FIG. 1C, a gate dielectric layer 130 is present, illustrated here as a layer above the upper surface 112 of the substrate (though this is not required). A gate structure 150 is located over the gate dielectric layer 130. The gate structure also extends over the isolation regions 114, 115.

Referring now to the plan view of FIG. 1A, here the gate structure 150 is illustrated as passing across the width (in the X-axis) of the active region 120. A first side 152 and a second side 154 of the gate structure 150 also pass across the width of the active region 120. The gate structure divides the active region 120 into a first subregion 122 and a second subregion 124, which are completely separated from each other by the gate structure in this plan view. S/D regions 180 are present on opposite sides of the gate structure 150. Put another way, one S/D region is in the first subregion 122 of the active region, and the other S/D region is in the second subregion 124 of the active region. It is noted that the two subregions 122, 124 of the active region are relative to the gate structure 150, and the active region may have more subregions, as will be seen further herein.

The first side 152 and the second side 154 of the gate structure are not parallel to each other. A first end 156 of the gate structure is present over one isolation region 114, and a second end 158 of the gate structure is present over the other isolation region 115. This shape could also be described as a trapezoid, with the non-parallel sides extending across the active region.

The first end 156 has a gate length Lg1, and the second end 158 has a gate length Lg2. As seen in this top or plan view, Lg1>Lg2. This difference in length is intentionally made, and is not an artifact or due to errors in the processing method. In some particular embodiments, the difference between Lg1 and Lg2 is at least 0.5 nanometers (nm), or at least 0.6 nm, or at least 0.7 nm, or at least 0.8 nm, or at least 0.9 nm, or at least 1 nm, up to a maximum difference of 5.0 nm. In additional embodiments, Lg1 and Lg2 each have a minimum length of 1 nm, or 1.2 nm, or 1.4 nm, or 1.5 nm, or 1.6 nm, or 1.8 nm, or 2.0 nm. In other embodiments, the value of the shorter length (here, Lg2) divided by the greater length (here, Lg1) is 0.85 or lower, including 0.8 or lower, or 0.7 or lower, or 0.7 or lower, or 0.6 or lower. This ratio may have a minimum value of 0.3.

Because the first side 152 and the second side 154 of the gate structure are not parallel to each other, the channel length between the two S/D regions 180 will be different along the width of the gate structure 150. In other words, as one travels along the width of the gate structure from the first end 156 to the second end 158, the channel length between the two S/D regions will change. This is illustrated in the Y-axis cross-sectional views of FIG. 1B and FIG. 1C. In FIG. 1B, which is closer to the first end 156 of the gate structure, the channel has a length LgB between the two S/D regions 180. In FIG. 1C, which is closer to the second end 158 of the gate structure, the channel has a length LgC between the two S/D regions 180. Here, Lg1>LgB>LgC>Lg2. Dielectric spacers 184 are also illustrated around the gate structure 150.

The X-axis cross-sectional views of FIG. 1D and FIG. 1E also illustrate the difference due to the non-parallel sides of the gate structure 150. In FIG. 1D, the gate structure 150 and the channel 117 each pass entirely between the two isolation regions 114, 115. However, in FIG. 1E, the gate structure 150 and the channel 117 do not pass entirely between the two isolation regions 114, 115, and one S/D region 180 is visible from above.

Finally, gate vias 216 and S/D vias 218 are also illustrated in FIG. 1A. As schematically illustrated here, the gate vias 216 are outside of the active region 120, whereas the S/D vias are within the active region 120 and in an S/D region 180.

Continuing, in FIG. 1, three different drain currents Id1, Id2, and Id3 are indicated. Drain current Id3 is closer to the first end 156 of the gate structure, and drain current Id1 is closer to the second end 158 of the gate structure. Here, Id1>Id2>Id3, where the total drain current Id=Id1+Id2+Id3.

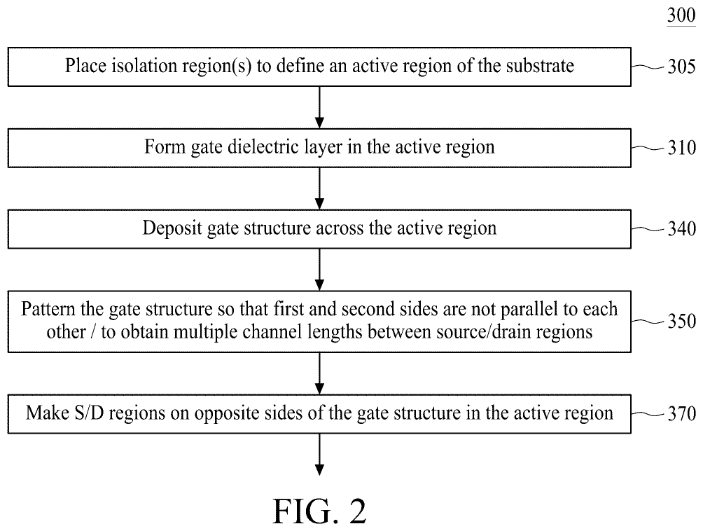

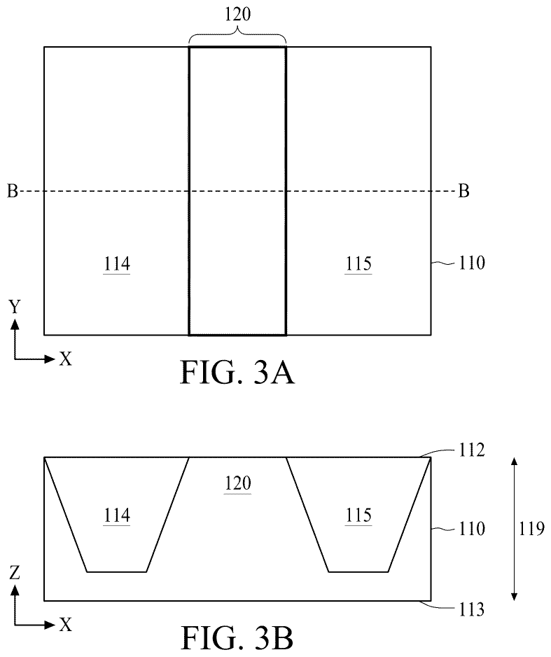

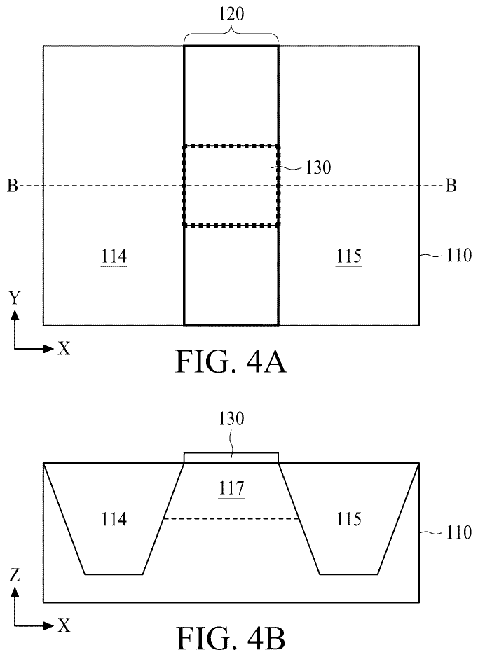

FIG. 2 is a flow chart illustrating a first method 300 for making a transistor 101, in accordance with some embodiments. Some steps of the method are also illustrated in FIGS. 3A-4B. These figures provide different views for better understanding.

Initially, FIG. 3A includes a substrate 110 upon which the transistor will be formed. The substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate includes an upper surface 112 and a lower surface 113, and generally has a constant thickness 119 between the two surfaces.

In step 305 of FIG. 2 and as illustrated in FIGS. 3A-3B, one or more isolation regions are placed in the substrate 110 to define an active region 120 of the substrate. The isolation regions may be, for example, shallow trench isolation (STI) regions or deep trench isolation (DTI) regions. The isolation regions may be made by patterning the substrate, etching isolation trenches, and filling the trenches with a dielectric material to obtain the isolation regions 114, 115. The dielectric material in the isolation region is commonly silicon dioxide, although other dielectric materials can also be used such as undoped polysilicon, silicon oxide (e.g. SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 112, then recessed back down to the desired height.

Next, in step 310 of FIG. 2 and as illustrated in FIG. 4A and FIG. 4B, a gate dielectric layer 130 is formed upon the substrate 110. CVD, PVD, atomic layer deposition (ALD), ion implantation, or other suitable deposition process may be used to form the gate dielectric layer. Thermal oxidation may also be used. The gate dielectric layer may be made, for example, from silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). Low-k or high-k dielectric materials may be used as desired. The gate dielectric layer is formed in the active region 120 between the isolation regions 114, 115. For reference, the semiconducting channel 117 is also indicated.

Next, in step 340 of FIG. 2 and referring to FIG. 1A, a gate structure 150 is deposited which extends across the active region. Next, in step 350, the gate structure is patterned so that the first side 152 and the second side 154 are not parallel to each other. These two steps may be performed concurrently or separately. For example, it is contemplated that a mask may be applied over the substrate that has a trapezoidal opening, and gate material is then deposited into the opening. As another example, gate material could be applied over the substrate, and subsequently patterned to obtain the trapezoidal shape. It is also contemplated that the shaping of the dielectric layer into a trapezoidal shape (i.e. so that it is only under the gate structure) may occur at the same time. Due to the shape of the gate structure, multiple semiconducting channel lengths will be formed between the two source/drain regions.

Then, in step 370 of FIG. 2, S/D regions 180 are made on opposite sides of the gate structure 150 in the active region 120. This may be done, for example, by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

The S/D regions may be n-wells or p-wells, depending on the dopant used. Common n-type dopants for silicon substrates may include phosphorus (P), arsenic (As), bismuth (Bi), or tantalum (Ta). Common p-type dopants for silicon substrates may include boron (B), aluminum (Al), gallium (Ga), or indium (In). Different dopants may be used for different substrates. For example, in gallium arsenide, n-type dopants may include tin (Sn), silicon (Si), or titanium (Ti). In gallium arsenide, p-type dopants may include beryllium (Be), zinc (Zn), chromium (Cr), silicon (Si), or germanium (Ge). In gallium phosphide, n-type dopants may include tellurium (Te), selenium (Se), sulfur(S), or oxygen (O). In gallium phosphide, p-type dopants may include zinc (Zn), magnesium (Mg), or tin (Sn). In cadmium telluride, n-type dopants may include indium (In), aluminum (Al), fluorine (F), chlorine (Cl), bromine (Br), or iodine (I). In cadmium telluride, p-type dopants may include (P), lithium (Li), or sodium (Na). In cadmium sulfide, n-type dopants may include (Ga), fluorine (F), chlorine (Cl), bromine (Br), or iodine (I). In cadmium sulfide, p-type dopants may include lithium (Li) or sodium (Na).

In the present disclosure, the gate structure 150 is formed prior to forming the S/D regions 180. As a result, different channel lengths between the S/D regions 180 are obtained.

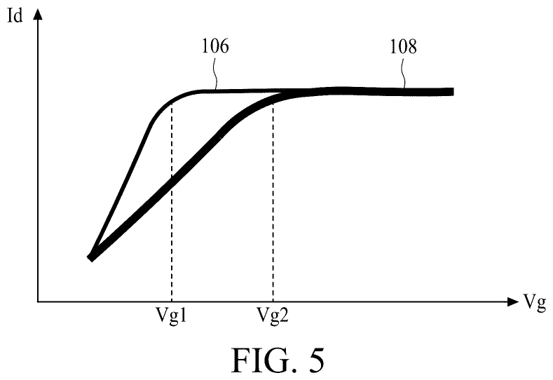

FIG. 5 is a graph of drain current vs. gate voltage, which indicates the difference in swing. Line 106 indicates swing performance in a transistor where the channel length is constant across the width of the active region. Line 108 indicates swing performance in a transistor where the channel length has multiple different values across the width of the active region, as described in the present disclosure. As indicated here, to obtain the same change in drain current, the gate voltage Vg2 for the multi-channel length transistor is greater than the gate voltage Vg1 for the single-channel length transistor. Put another way, the slope is lower for the multi-channel length transistor.

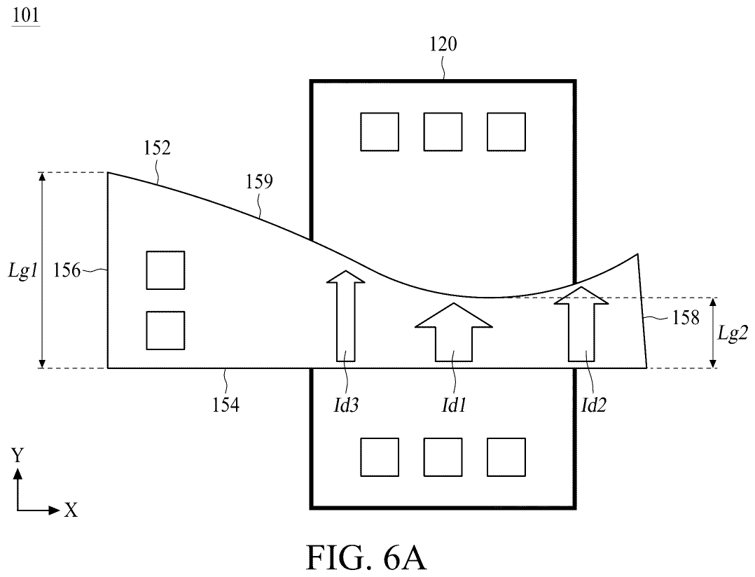

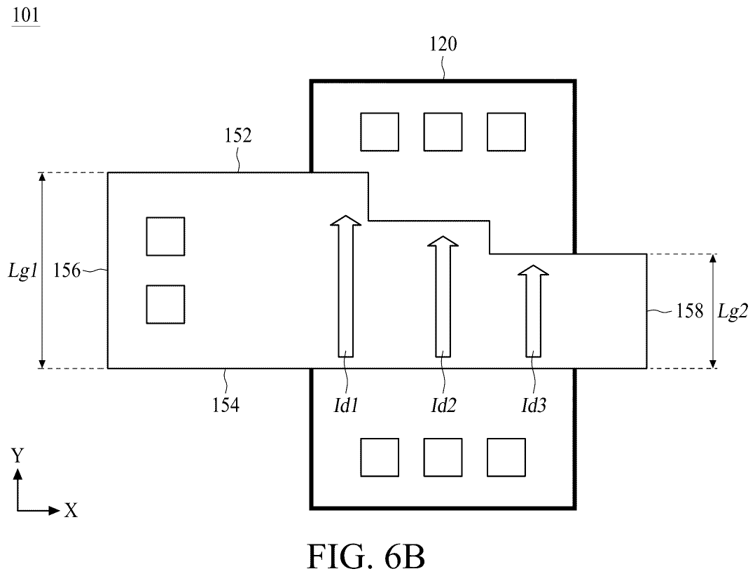

FIG. 6A and FIG. 6B illustrate two variations on the gate structure 150. In FIG. 1A, the first side 152 of the gate structure tapers linearly from the first end 156 to the second end 158, which could be considered as providing an infinite number of different channel lengths. In FIG. 6A, the first side 152 includes at least one curved segment 159, with the channel length being lowest in the middle of the active region (indicated by value Lg2) instead of at one end as in FIG. 1A. This is indicated by Id1 being in the middle. Any combination of linear and curved segments may be used to form the first side 152. In FIG. 6B, the first side 152 may be described as a stepped structure, such that three specific different channel lengths are formed within the active region 120. Generally, any number of steps may be provided.

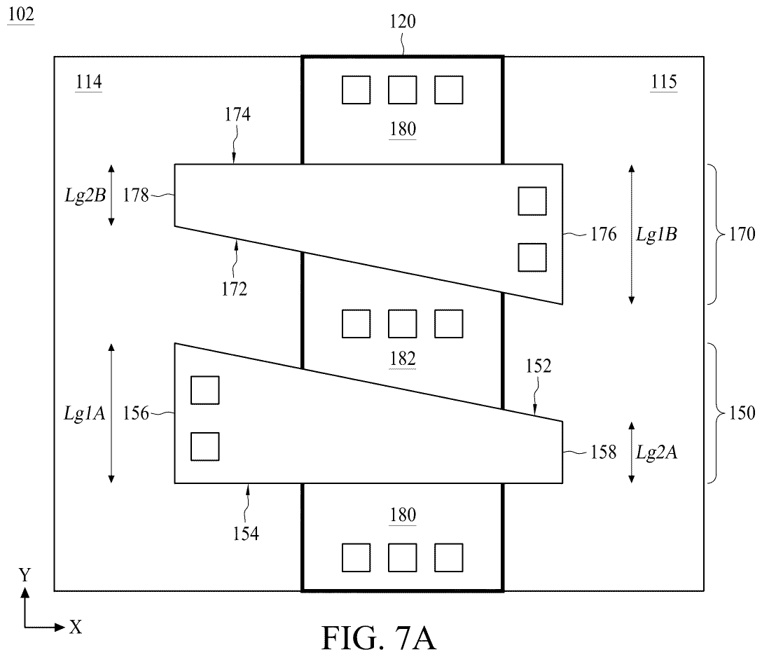

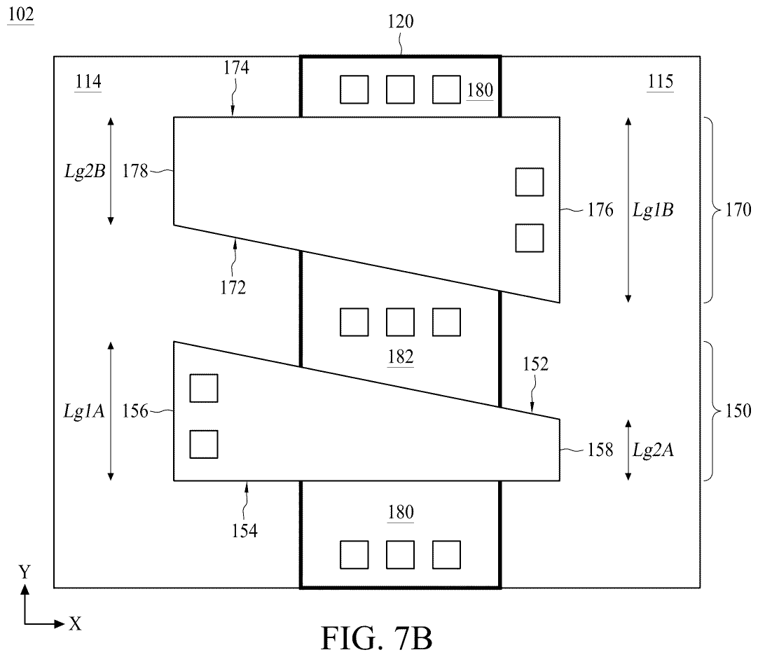

FIG. 7A and FIG. 7B illustrate two variations of composite transistors 102. Here, two separate gate structures 150, 170 are formed that extend across a common active region 120. The active region is thus divided into three subregions or S/D regions 180, with the two transistors sharing a common S/D region 182.

As can be seen here, the first gate structure 150 is oriented with its longer first end 156 above isolation region 114 and its shorter second end 158 above isolation region 115. In contrast, the second gate structure 170 is flipped, and is oriented with its longer first end 176 above isolation region 115 and its shorter second end 178 above isolation region 114. Thus, the first sides 152, 172 of each gate structure are adjacent to the common S/D region 182. This may shorten the pitch of the two transistors, increasing transistor density. These composite transistors can be made as described in FIG. 2, with appropriate masks.

For the first gate structure, the first end 156 has a gate length Lg1A, and the second end 158 has a gate length Lg2A. For the second gate structure, the first end 176 has a gate length Lg1B, and the second end 178 has a gate length Lg2B. Lg1A>Lg2A and Lg1B>Lg2B.

In some particular embodiments as illustrated in FIG. 7A, the two first sides 152, 172 may be parallel to each other. The two second sides 154, 174 may also be parallel to each other. In the embodiment of FIG. 7A, Lg1A=Lg1B, and Lg2A=Lg2B. However, these relationships are not required.

For example, as illustrated in the embodiment of FIG. 7B, Lg1A>Lg2A and Lg1B>Lg2B. However, Lg1B is also greater than Lg1A (Lg1B >Lg1A). Lg2B can be greater than Lg1A (Lg2B>Lg1A), or vice versa (Lg1A>Lg2B). In these embodiments, Lg2A would be the shortest length of the four lengths. The prior discussion about minimum lengths, differences between lengths, and ratios in FIG. 1A applies to these embodiments as well.

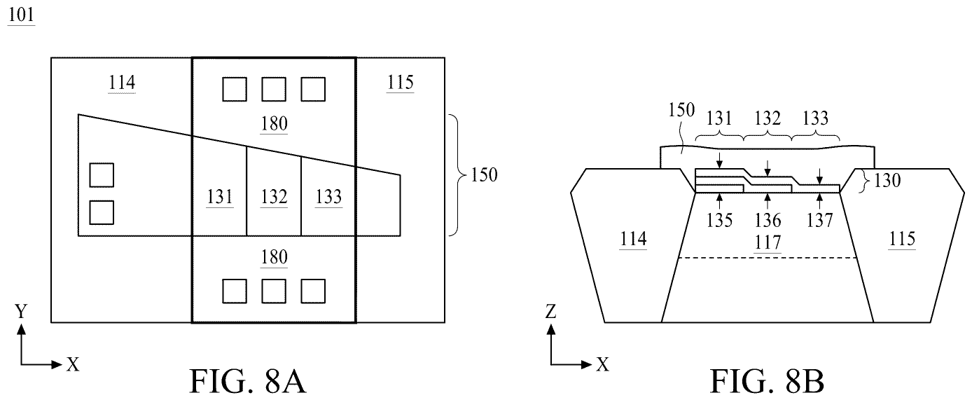

FIG. 8A and FIG. 8B show another variation of the transistor 101, in accordance with some embodiments of the present disclosure. Here, the thickness of the gate dielectric layer 130 varies in different regions extending between the two S/D regions 180. The gate dielectric layer can be described as being divided into a plurality of regions, illustrated here as three regions 131, 132, 133. FIG. 8A is shown with the gate structure removed in the active region, so that the plan-view shapes of the three regions are visible. The second region 132 is between the first and third regions 131, 133. As seen in FIG. 8B, the thickness (in the Z-axis) of the gate dielectric layer 135, 136, 137 is also different in each region. As a result, the effective dielectric constant of the gate dielectric layer is different in each region, which corresponds to different gate capacitances that will affect the leakage current flowing through the gate dielectric layer.

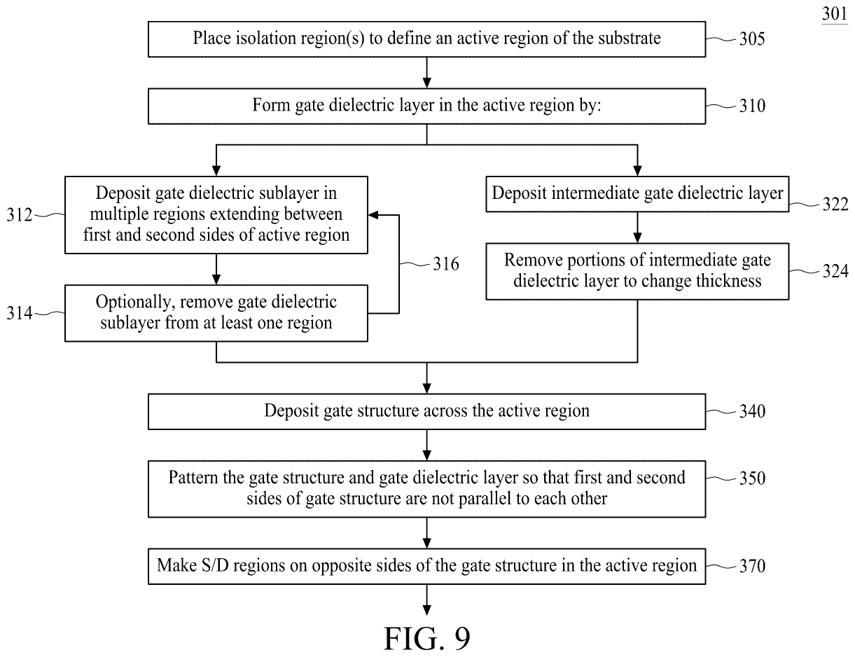

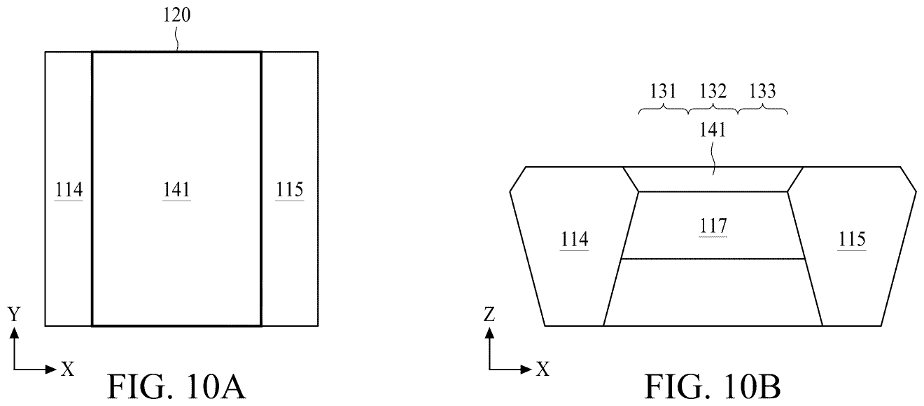

FIG. 9 is a flow chart illustrating a second method 301 for making a transistor 101 with a gate dielectric layer as illustrated in FIGS. 8A-8B, in accordance with some embodiments. Some steps of the method are also illustrated in FIGS. 10A-15B. These figures provide different views for better understanding.

Initially, in step 305 of FIG. 9 and as previously discussed, one or more isolation regions 114, 115 are placed in the substrate to define an active region 120 of the substrate. This may be done as previously described. Next, in step 310 of FIG. 9, a gate dielectric layer 130 is formed upon the substrate 110. This may be done in at least two different ways, as indicated.

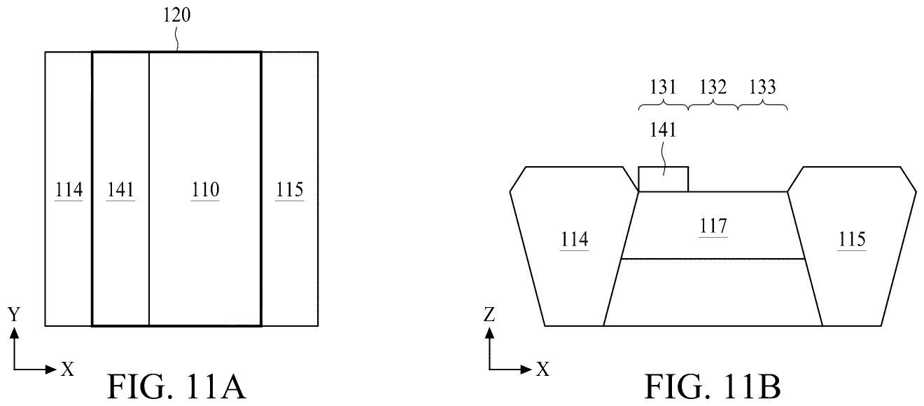

In one branch, in step 312 of FIG. 9 and as illustrated in FIG. 10A and FIG. 10B a first gate dielectric sublayer 141 is deposited over the active region 120. CVD, PVD, ALD, thermal oxidation, or other suitable process may be used to form the first gate dielectric sublayer. The first gate dielectric sublayer 141 is present in all three regions 131, 132, 133. Then, in optional step 314 of FIG. 9 and as illustrated in FIG. 11A and FIG. 11B, the first gate dielectric sublayer 141 is removed from at least one region. This may be done, for example, by etching or other suitable process. Here, the first gate dielectric sublayer 141 is removed from the second and third regions 132, 133. In the plan view of FIG. 11A, the substrate 110 is visible. These two steps are repeated for as many regions as desired, as indicated by step 316.

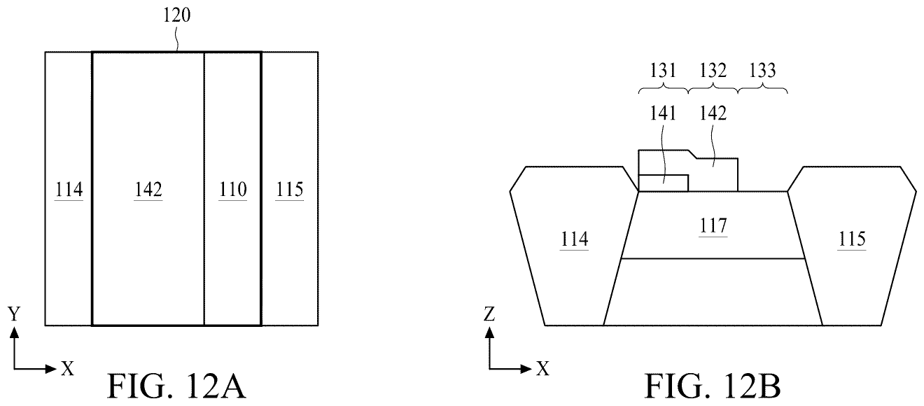

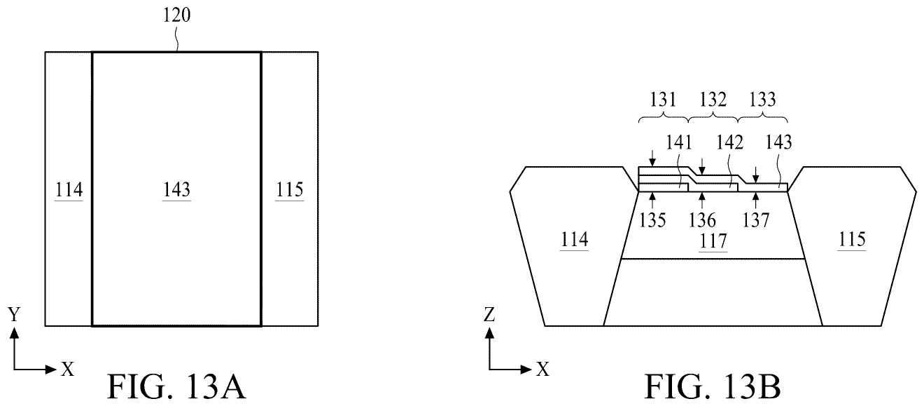

For example, as illustrated in FIG. 12A and FIG. 12B, a second gate dielectric sublayer 142 is deposited in all three regions and then removed from the third region 133. As illustrated in FIG. 13A and FIG. 13B, a third gate dielectric sublayer 143 is deposited in all three regions according to step 312, but is not removed from any of the regions. The resulting gate dielectric layer 130 is thus formed from the combination of the three gate dielectric sublayers 141, 142, 143. The gate dielectric layer has a thickness 135 in the first region 131 formed from all three gate dielectric sublayers, a different thickness 136 in the second region 132 formed from two gate dielectric sublayers, and a different thickness 137 in the third region 133 formed from only gate dielectric sublayer 143. While the greatest thickness is illustrated in the first region 131 adjacent to isolation region 114, this is not required. For example, the greatest thickness could be present in the third region 133 adjacent to isolation region 115.

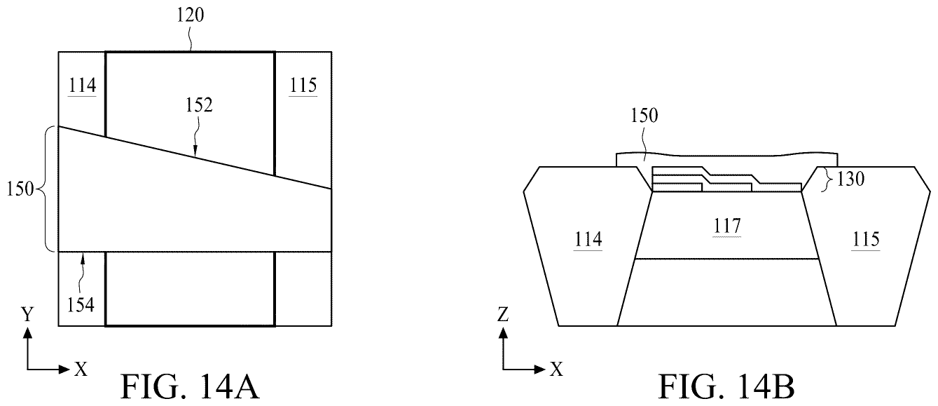

Continuing, in step 340 of FIG. 9 and referring to FIG. 14A and FIG. 14B, a gate structure 150 is deposited which extends across the active region 120. Then, in step 350, the gate structure 150 is patterned so that the first side 152 and the second side 154 are not parallel to each other. Comparing FIG. 13A to FIG. 14A, it can be seen that the portions of the gate dielectric layer 130 not located below the gate structure 150 are removed, thus exposing the two sides of the active region. Then, in step 370 of FIG. 9, S/D regions are made on opposite sides of the gate structure 150 in the active region 120. The resulting structure is shown in FIG. 8A and FIG. 8B.

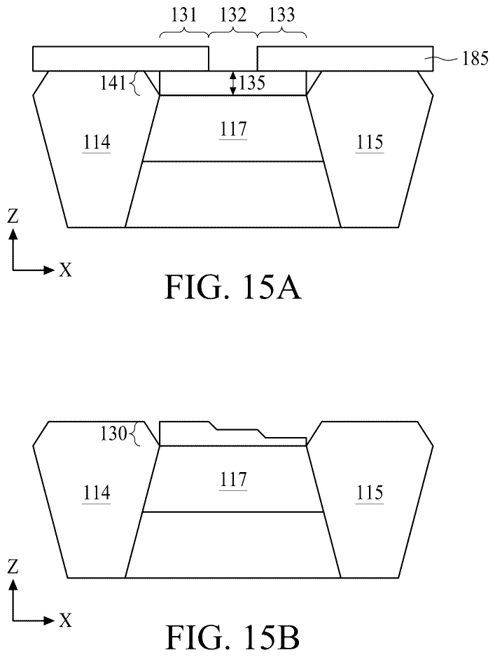

In the second branch of FIG. 9, in step 322, an intermediate gate dielectric layer is deposited over the active region 120. This can correspond to the first gate dielectric sublayer 141 as illustrated in FIG. 10A and FIG. 10B, and having a thickness 135. Then, in step 324 of FIG. 9, portions of the intermediate gate dielectric layer are removed to change its thickness and obtain the final gate dielectric layer. For example, FIG. 15A illustrates a mask 185 placed over the intermediate gate dielectric sublayer 141 for reducing the thickness in the second region 132. FIG. 15B illustrates the final gate dielectric layer 130. Compared to FIG. 13B, the main difference is that only one material is used. This second branch may be useful, for example, if the intermediate gate dielectric layer is made of silicon dioxide, which can then be partially etched to reduce its thickness and provide different effective dielectric constants through the gate dielectric layer. Steps 340, 350, and 370 may then be performed as described above.

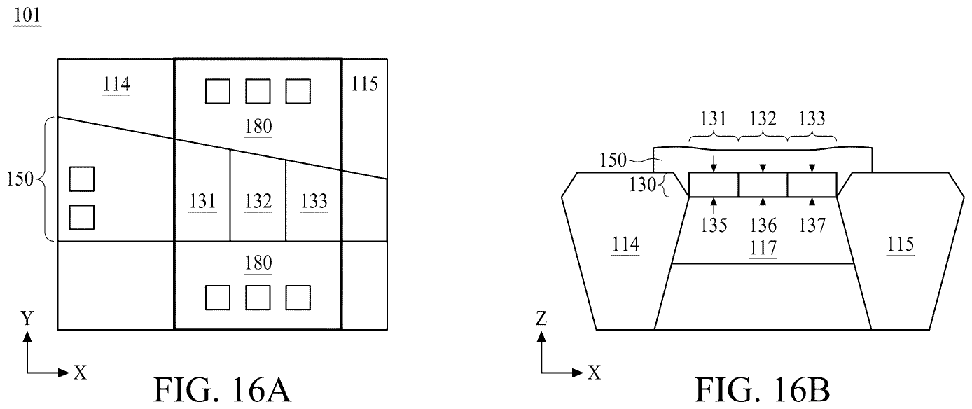

FIG. 16A and FIG. 16B show another variation of the transistor 101, in accordance with some embodiments of the present disclosure. Here, the dielectric constant of the gate dielectric layer 130 varies in different regions extending between the two S/D regions 180. The gate dielectric layer can be described as being divided into a plurality of regions, illustrated here as three regions 131, 132, 133. FIG. 16A is shown with the gate structure removed in the active region, so that the plan-view shapes of the three regions are visible. As seen in FIG. 16B, the thickness (in the Z-axis) of the gate dielectric layer 135, 136, 137 is the same in each region. The effective dielectric constant of the gate dielectric layer is thus different in each region. Adjacent gate dielectric regions have different K values. It is possible for the first region 131 and the third region 133 to have the same effective K value.

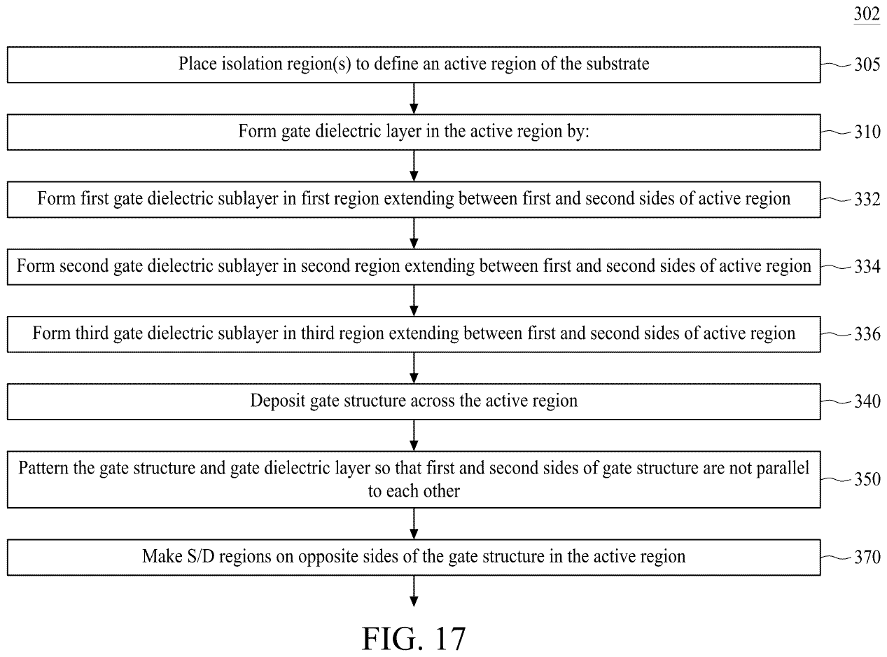

FIG. 17 is a flow chart illustrating a third method 302 for making a transistor 101 with a gate dielectric layer as illustrated in FIGS. 16A-16B, in accordance with some embodiments. Initially, in step 305 of FIG. 17, one or more isolation regions 114, 115 are placed in the substrate to define an active region 120 of the substrate. This may be done as previously described.

Next, in step 310, a gate dielectric layer 130 is formed upon the substrate 110. This may be done by growing or depositing dielectric material in each of the three regions 131, 132, 133 that make up the gate dielectric layer. Examples of suitable dielectric materials include those previously discussed. As indicated here, in step 332, a first gate dielectric sublayer is formed in the first region 131, which extends between the first and second subregions 122, 124 of the active region. In step 334, a second gate dielectric sublayer is formed in the second region 132. In step 336, a third gate dielectric sublayer is formed in the third region 133. It is noted that in some embodiments, the same material may be used in the first and third regions 131, 133. Steps 340, 350, and 370 may then be performed as described above to obtain the structure as illustrated in FIGS. 16A-16B.

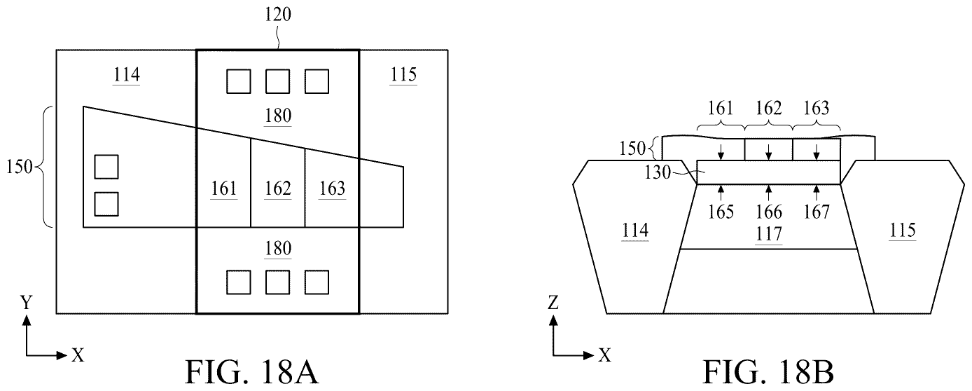

FIG. 18A and FIG. 18B show another variation of the transistor 101, in accordance with some embodiments of the present disclosure. Here, the work function of the gate structure 150 varies in different regions extending between the two S/D regions 180. The gate structure can thus be described as being divided into a plurality of regions, illustrated here as three regions 161, 162, 163. As seen in FIG. 18A, each of the three regions extends between the two subregions of the active region/the two S/D regions 180. The plan-view shapes of the three regions of the gate structure are visible. As seen in FIG. 16B, the thickness (in the Z-axis) of the gate structure 165, 166, 167 is the same in each region. The effective dielectric constant of the gate dielectric layer is thus different in each region. Adjacent gate dielectric regions have different work function values. It is possible for the first region 161 and the third region 163 to have the same effective work function value. This may reduce the “double hump phenomenon” in the drain current vs. gate voltage curve by increasing the corner device resistance.

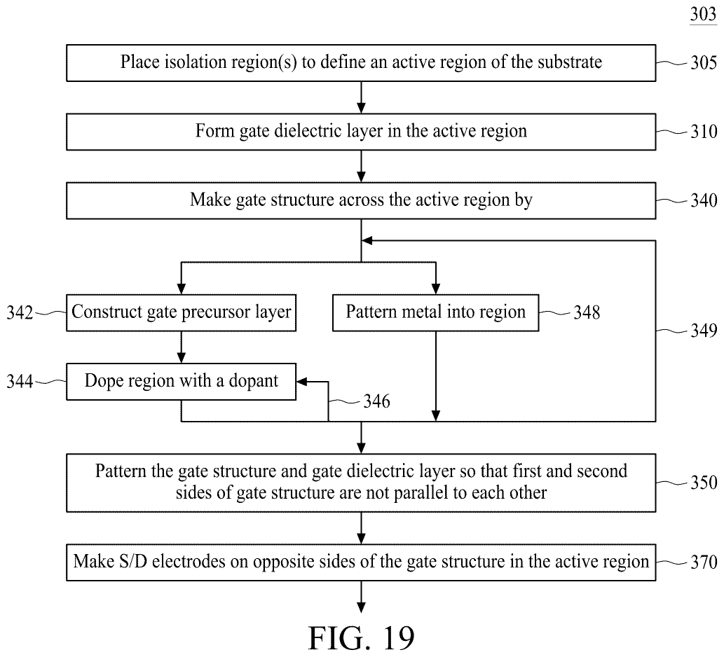

FIG. 19 is a flow chart illustrating a fourth method 303 for making a transistor 101 with a gate structure as illustrated in FIGS. 18A-18B, in accordance with some embodiments. Initially, in step 305 of FIG. 19, one or more isolation regions 114, 115 are placed in the substrate to define an active region 120 of the substrate. Next, in step 310, a gate dielectric layer 130 is formed upon the substrate 110. These steps may be performed as previously described.

Next, in step 340 of FIG. 19, a gate structure 150 is made upon the substrate 110 and across the active region. This may be done in at least two different ways, as indicated.

First, in step 342 of FIG. 19, a gate precursor layer is constructed across the active region. The gate precursor layer may be made in only some of the three regions 161, 162, 163, if desired. The gate precursor layer may also extend over both isolation regions 114, 115. This may be done by CVD, PVD, or other suitable process. In particular embodiments, the gate precursor layer is made of polysilicon. Then, in step 344, desired portions of the gate precursor layer are doped to obtain a functioning gate region. N-type and p-type dopants may be used as desired and using methods previously described. For example, a first gate portion in first region 161 may be doped with a p-type dopant, and a second gate portion in second region 162 may be doped with an n-type dopant to obtain desired work functions. Any number of different dopants may be used, as indicated by repeating step 346.

Alternatively, as described in step 348 of FIG. 19, a region of the gate structure, for example third region 163, may be formed by deposition and patterning of a metal or metal alloy. Suitable metals may include, for example, W, TiN, TiAl, Pt, Co, Rh, Pd, Ti, or Ta. Suitable processes such as CVD, PVD, ALD, or other deposition techniques may be used. The regions of the gate structure may be formed in any order, using either method, as indicated by arrow 349. Steps 350 and 370 may then be performed as described above to obtain the structure as illustrated in FIGS. 18A-18B.

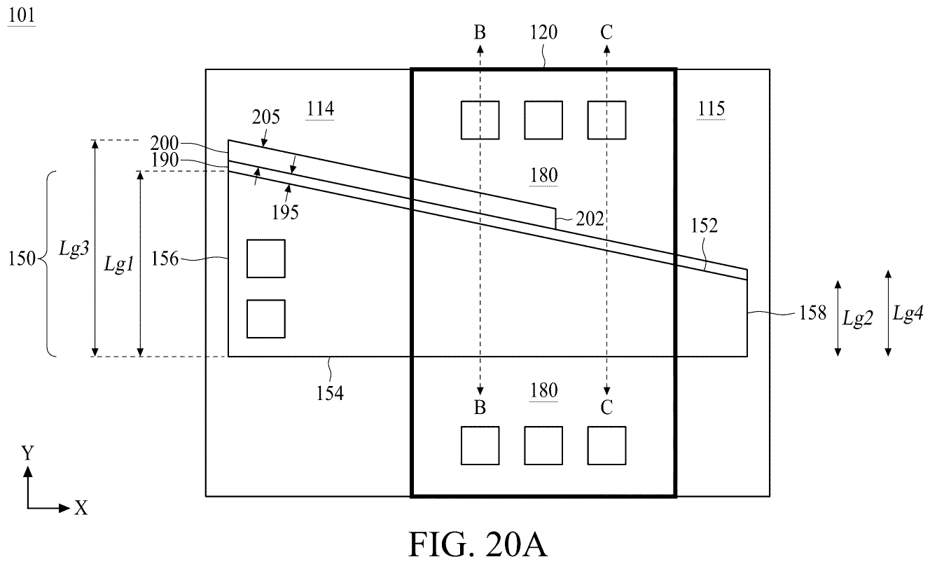

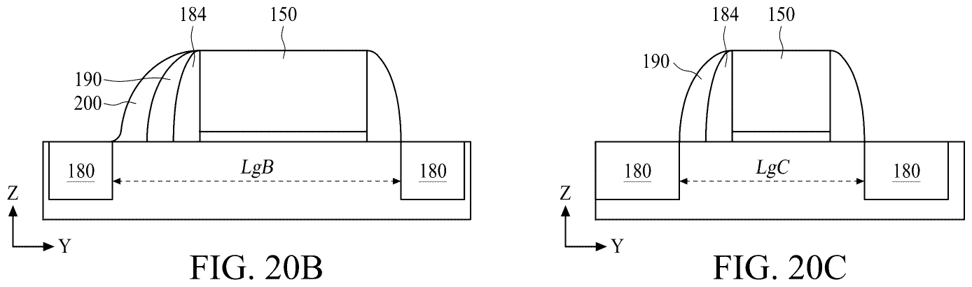

FIGS. 20A-20C show another variation of the transistor 101, in accordance with some embodiments of the present disclosure. Initially, the gate structure has non-parallel opposite sides 152, 154. Dielectric spacers 184 are also illustrated in FIGS. 20B-20C on either side of the gate structure 150. Here, a first dielectric sidewall 190 is shown on the first side 152 of the gate structure. The first dielectric sidewall extends along the entire first side 152 from the first end 156 to the second end 158 of the gate structure. As also illustrated here, a second dielectric sidewall 200 is adjacent to the first dielectric sidewall 190. In contrast, the second dielectric sidewall extends across only a portion of the gate structure 150 or the active region 120. Put another way, one end 202 of the second dielectric sidewall is present over the active region 120, or the second dielectric sidewall terminates over the active region. In this embodiment illustrated in FIG. 20A, the first dielectric sidewall 190 has a constant length 195. The second dielectric sidewall 200 also has a constant length 205. Thus, the first end 156 of the gate structure may be described as having a length Lg1 and the second end 158 of the gate structure may be described as having a length Lg2. When the lengths of the two dielectric sidewalls are considered, the first end has a length Lg3 and the second end has a length Lg4.

In particular embodiments, the second dielectric sidewall 200 is a resist protective oxide (RPO) layer. The RPO layer may be a dielectric material, such as silicon dioxide, silicon oxynitride, or other suitable material. This layer may be formed using CVD, PVD, ALD, or other suitable deposition technique.

As a result, the differences in the channel length between the two S/D regions 180 along the width of the gate structure 150 may be greater than a structure without a first dielectric sidewall and/or second dielectric sidewall (such as that illustrated in FIGS. 1A-1C). This is illustrated again in the Y-axis cross-sectional views of FIG. 20B and FIG. 20C. In FIG. 20B, which is closer to the first end 156 of the gate structure, the channel has a length LgB between the two S/D regions 180. This channel length is determined by the combination of the gate structure 150, the dielectric spacer 184, the first dielectric sidewall 190, and the second dielectric sidewall 200. In FIG. 20C, which is closer to the second end 158 of the gate structure, the channel has a length LgC between the two S/D regions 180 which is determined by the combination of only the gate structure 150, the dielectric spacer 184, and the first dielectric sidewall 190. Again, Lg3>LgB>LgC>Lg2.

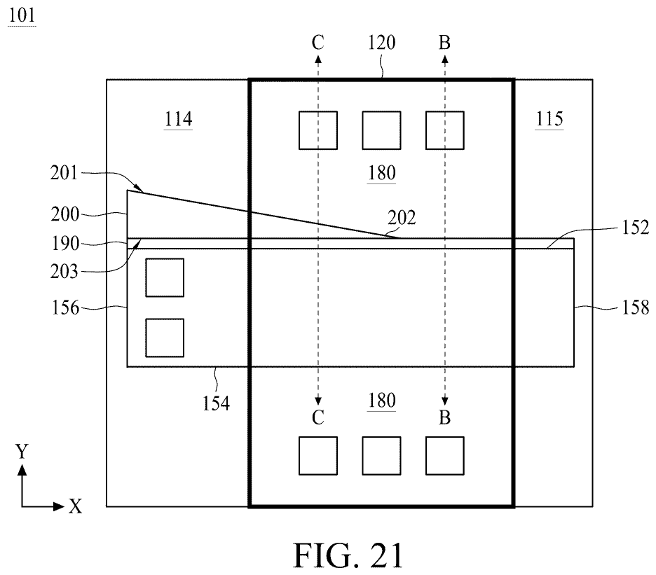

FIG. 21 shows another variation of the transistor of FIGS. 20A-20C. In this plan view, the first and second sides 152, 154 of the gate structure are parallel to each other. A first dielectric sidewall 190 is shown on the first side 152 of the gate structure. A second dielectric sidewall 200 with non-parallel sides 201, 203 is present extending from the first end 156 of the gate structure and extending across only a portion of the active region. This structure will operate in the same manner as FIGS. 20A-20C to provide different channel lengths across the width of the gate structure.

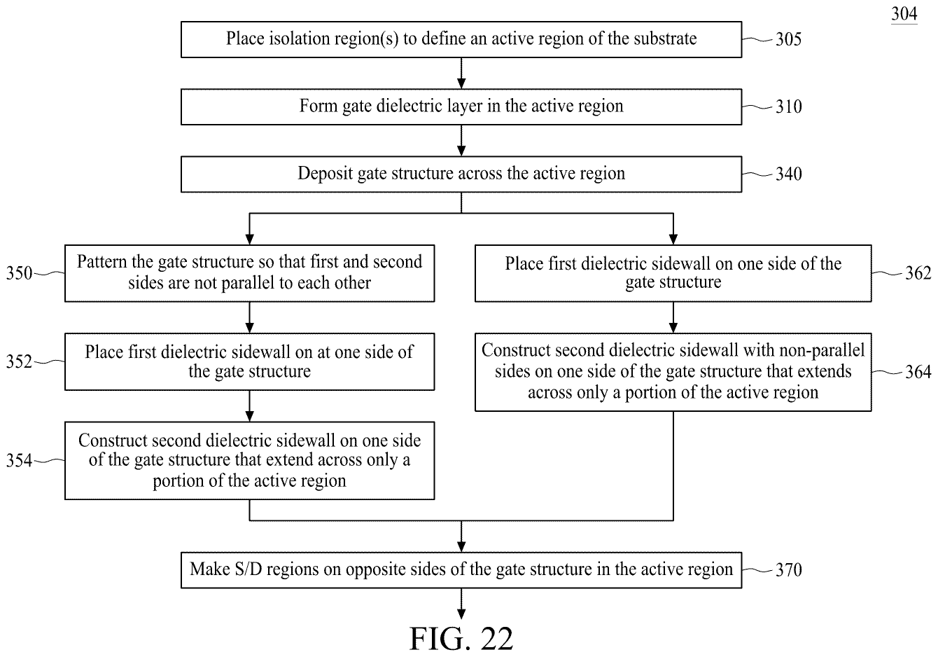

FIG. 22 is a flow chart illustrating a fifth method 304 for making a transistor 101 with a gate structure as illustrated in FIGS. 20A-20C or FIG. 21, in accordance with some embodiments. Initially, in step 305 of FIG. 22, one or more isolation regions 114, 115 are placed in the substrate to define an active region 120 of the substrate. Next, in step 310, a gate dielectric layer 130 is formed upon the substrate 110. Then, in step 340, a gate structure 150 is deposited upon the substrate 110 and across the active region. These steps may be performed as previously described. Next, two different pathways are followed, depending on whether the structure of FIGS. 20A-20C or the structure of FIG. 21 is desired.

To obtain the structure of FIGS. 20A-20C, in step 350 of FIG. 22, the gate structure is patterned so that the first side 152 and the second side 154 are not parallel to each other. Next, in step 352, a first dielectric sidewall 190 is placed on one side of the gate structure. This dielectric sidewall extends entirely across the active region. Then, in step 354, a second dielectric sidewall 200 is constructed on one side of the gate structure which extends across only a portion of the active region.

To obtain the structure of FIG. 21, in step 362 of FIG. 21, the first dielectric sidewall 190 is placed on one side of the gate structure. This dielectric sidewall extends entirely across the active region. Then, in step 354, a second dielectric sidewall 200 is constructed on one side of the gate structure which extends across only a portion of the active region. The second dielectric sidewall has non-parallel sides. As a result, the channel length varies across the width of the active region. Step 370 may then be performed as described above to obtain the desired structure.

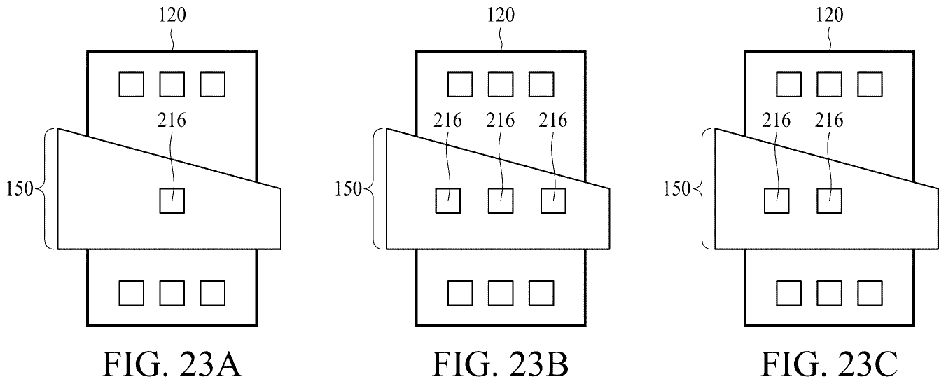

As illustrated in FIGS. 23A-23C, one or more gate vias 216 can be placed over the active region. This is in contrast to FIG. 1A, where the gate vias 216 are placed over an isolation region 114. Their number, position, size, and/or bias may be controlled to change the electric field applied by the gate structure so as to further adjust the current flow between the two S/D regions. In FIG. 23A, one gate via 216 is present in the center of the active region 120. In FIG. 23B, three gate vias 216 are evenly spaced across the width of the active region 120. In FIG. 23C, two gate vias 216 are placed on one side and in the center of the active region 120.

It is noted that the various embodiments disclosed above can be combined in any desired manner. As one example, the gate dielectric layer 130 illustrated in FIGS. 8A-8B could be combined with the gate structure illustrated in FIGS. 18A-18B and the dielectric sidewalls illustrated in FIG. 20A. As another example, the gate dielectric layer 130 illustrated in FIGS. 16A-16B could be combined with the gate structure illustrated in FIGS. 18A-18B.

Additional processing steps may be performed to fabricate additional structures as desired. Examples of such steps may include ion implantation, deposition of other materials, etching, etc.

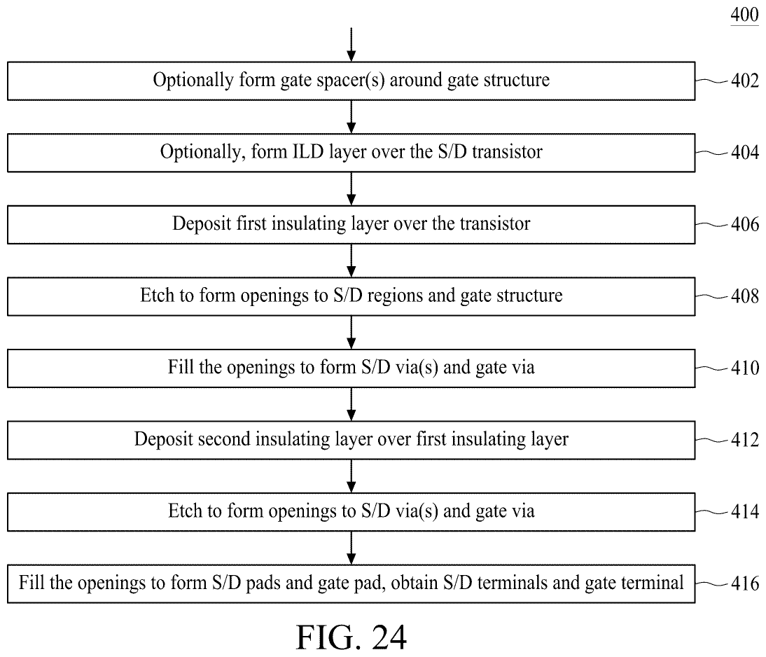

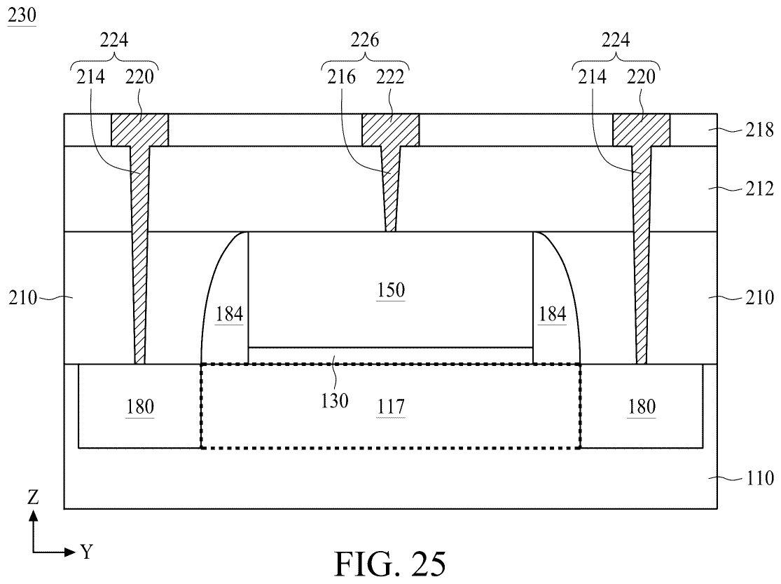

Further processing may occur to package the transistor. FIG. 24 is a flow chart illustrating a method 400 for forming a semiconductor package 230, in accordance with some embodiments. Various steps of this method are shown in FIG. 25. It is contemplated that this method would be practiced after the methods of FIG. 2, FIG. 9, FIG. 17, FIG. 19, FIG. 22, and variations thereof are performed.

Referring first to FIG. 25, the substrate 110, gate dielectric layer 130, gate structure 150, and S/D regions 180 are visible. Continuing, then, in optional step 402 of FIG. 24, at least one gate spacer 184 may be formed upon the sidewalls of the gate structure 150. The gate spacer(s) are vertically oriented, and have a relatively narrow width. The gate spacers can be made from a dielectric material for electrical isolation of the gate structure. In particular embodiments, the gate spacer(s) are silicon nitride (SiN) or silicon dioxide (SiO₂). The gate spacer(s) can be made by CVD, PVD, ALD, or other deposition technique.

Next, in optional step 404 of FIG. 24, an interlayer dielectric (ILD) material can be applied over the S/D regions 180 to form ILD regions 210. The ILD regions electrically separate the S/D regions 180 from the gate structure 150. The ILD regions may be formed from any dielectric material, and do not need to be a high-k dielectric material. The ILD material can be deposited using any appropriate method, for example CVD.

Next, in step 406 of FIG. 24, a first insulating layer 212 is deposited over the active region, including the S/D regions 180 and the gate structure 150. This layer may be formed using processes such as PVD, CVD, SACVD, or other suitable deposition process. The material for the first insulating layer may be silicon or other suitable dielectric material (e.g. silicon dioxide).

Then, in step 408 of FIG. 24, etching is performed to form openings that extend through the first insulating layer 212 and the ILD regions 210 to the S/D regions 180 and the gate structure 150. In step 410, the openings are then filled with an electrically conductive material to form source/drain vias 214 and gate via(s) 216. The first insulating layer may also be considered to be an interconnect layer that permit various components to communicate with each other, or a redistribution layer (RDL).

The vias 214, 216 themselves may be sufficient to act as a terminal (i.e. a source terminal, a drain terminal, and a gate terminal) for further processing steps. If a larger contact footprint is desired, these steps can be repeated.

For example, in step 412 of FIG. 24, a second insulating layer 218 is deposited upon the first insulating layer 212. Then, in step 414, etching is performed to form openings that extend through the second insulating layer 218 to the vias 214, 216 in the first insulating layer. In step 416, the openings are then filled with an electrically conductive material to form source/drain pads 220 and a gate pad 222. S/D terminals 224 are formed from the combination of an S/D via 214 and an S/D pad 220. A gate terminal 226 is formed from the combination of a gate via 216 and a gate pad 222. It is noted that the gate terminal 226 is usually separated from the S/D terminals 224 in at least one axis.

It is also noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

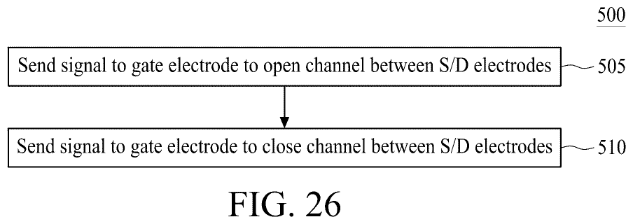

FIG. 26 is a flow chart illustrating a method 500 for operating a semiconductor device or transistor, in accordance with some embodiments. Reference is also made to the structure of FIG. 25.

In step 505 of FIG. 26, a signal is sent to a gate structure 150. Typically, a voltage signal is sent, either in the form of an increased voltage or a decreased voltage (depending on how the gate structure is operated). This opens a channel 117 between the S/D regions 180, which permits current to flow between them. In step 510 of FIG. 26, a different signal is sent to the gate structure 150 to close the channel 117.

The transistors of the present disclosure have a combination of advantages. The transistor have high subthreshold swing performance. Device size can be reduced as well. Robust devices with higher operational frequency can be obtained.

The transistors of the present disclosure are especially useful for high voltage, medium voltage, and low voltage devices on chips. High voltage devices typically operate from about 12 volts (V) to about 28V. Medium voltage devices typically operate from about 3V to about 9V. Low voltage devices usually operate below 1V.

The semiconductor devices might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc. ; power management devices that control the flow and direction of electrical power; and/or image signal processors (ISP).

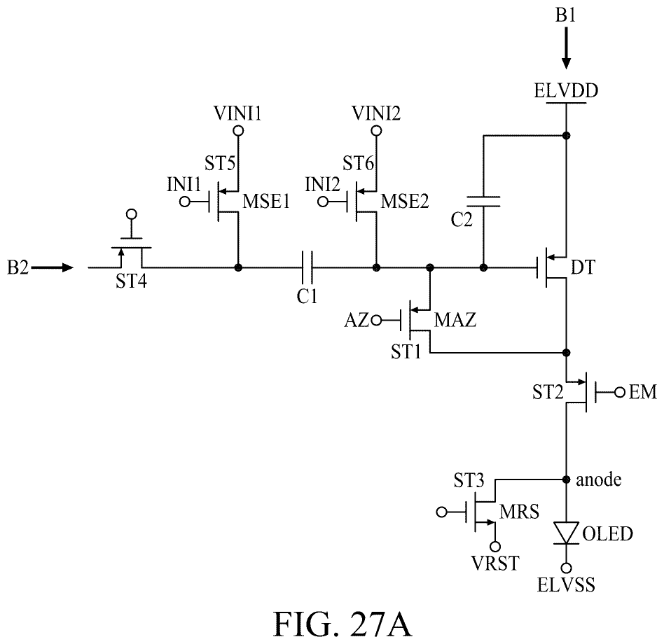

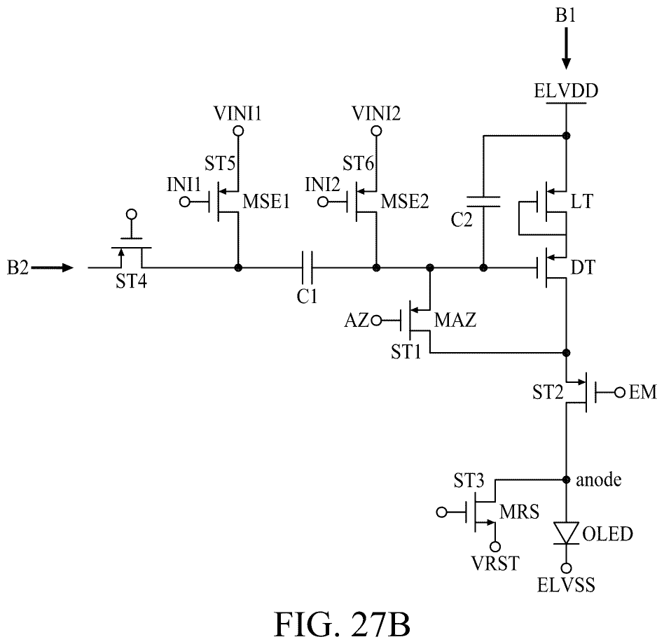

FIG. 27A and FIG. 27B are circuit diagrams showing illustrative embodiments of pixel driver circuits in which the transistors of the present disclosure can be used. In FIG. 27A, a 7T2C circuit containing seven transistors and 2 capacitors is illustrated. The transistors of the present disclosure having high subthreshold swing performance and reduced hysteresis are especially useful as the driving transistor DT. Six switching transistors ST1, ST2, ST3, ST4, ST5, and ST6 are also illustrated along with two capacitors C1, C2. The switching transistors can be optimized for lower leakage, or larger breakdown voltage, for example.

A first branch B1 runs from the power supply ELVDD to the pixel represented by diode OLED, and includes the driving transistor DT and switching transistor ST2 in series. Switching transistor ST3 is in parallel to the diode, and is connected to a reset voltage signal V_{RST}. A second branch B2 running perpendicular to the first branch includes switching transistor ST4 and capacitor C1 in series and running to the gate of the driving transistor DT. Switching transistors ST5 and ST6 intersect the second branch B2 on either side of capacitor C1, and are used to control the voltage of C1. These two transistors connect to initialization voltage signals V_{INI1} and V_{INI2}, respectively. Switching transistor ST1 connects to the second branch B2 upstream of the driving transistor DT, and connects to the first branch B1 between the driving transistor DT and the switching transistor ST2. Capacitor C2 connects to the first branch B1 between the power supply ELVDD and the driving transistor DT, and connects to the second branch B2 between switching transistor ST1 and the driving transistor DT.

Operation of this circuit includes an initialization phase, detection phase, data writing phase, and emitting phase. The driving transistor DT controls the amount of current flowing from the power supply ELVDD to the pixel represented by diode OLED during the emitting phase. Capacitor C1 stores the voltage representing the desired brightness of the pixel. The various switching transistors are used for receiving and controlling various voltage signals, compensating for variations, and resetting the circuit.

FIG. 27B is a circuit diagram showing a second example embodiment of a pixel driver circuit in which the transistors of the present disclosure can be used. This circuit diagram is an 8T2C circuit, and includes a diode-connected limiting transistor LT located on the first branch B1 in series between the power supply ELVDD and the driving transistor DT. Limiting transistor LT is also located between capacitor C2 and the driving transistor DT. This can be used, for example, to limit the current.

Some embodiments of the present disclosure thus relate to methods for forming a transistor. Isolation regions are formed in a substrate on opposite sides of an active region. A gate dielectric layer is formed between the isolation regions in the active region. This divides the active region into a first subregion and a second subregion on opposite sides of the gate dielectric layer. A gate structure is formed over the gate dielectric layer. The gate structure comprises a first side adjacent to the first subregion of the active region and a second side adjacent to the second subregion of the active region. The first side is not parallel to the second side. Source/drain (S/D) regions are then formed on opposite sides of the gate structure in the two subregions of the active region.

Also disclosed in various embodiments are transistors that comprise a drain region and a source region. The source region and the drain region are disposed on opposite sides of a gate structure. The gate structure comprises a first side adjacent to the drain region and a second side adjacent to the source region. The first side is not parallel to the second side.

Also disclosed in various embodiments are transistors that comprise a drain region, a source region, and a gate structure between the source region and the drain region. The channel length between the source region and the drain region changes along a width of the gate structure.

Also disclosed are semiconductor devices comprising one or more transistors having the structures described above. The transistor(s) may be packaged, for example with ILD regions and insulating layer(s) as described above, with vias/terminals extending through the insulating layer(s).

Also disclosed are methods for operating a transistor. A voltage signal to a gate structure is changed to open a channel between two source/drain regions. The transistor has at least one of the structures described above.

Also disclosed are other methods for making a transistor. A gate structure is formed on a substrate across an active region. A dielectric sidewall is formed on one side of the gate structure that extends across only a portion of the active region. A first side and a second opposite side of the second dielectric sidewall are not parallel to each other. Source/drain regions are then formed on opposite sides of the gate structure in the active region.

The methods, systems, and devices of the present disclosure are further illustrated in the following non-limiting working examples, it being understood that they are intended to be illustrative only and that the disclosure is not intended to be limited to the materials, conditions, process parameters and the like recited herein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a transistor, comprising:
forming a gate dielectric layer in an active region, and dividing the active region into a first subregion and a second subregion on opposite sides of the gate dielectric layer;
depositing a gate structure over the gate dielectric layer, the gate structure comprising a first side adjacent to the first subregion of the active region and a second side adjacent to the second subregion of the active region, wherein the first side is not parallel to the second side; and
making source/drain (S/D) regions in the first and second subregions of the active region on opposite sides of the gate structure.

2. The method of claim 1, wherein the gate dielectric layer is formed by:
depositing a first gate dielectric sublayer in a first region and a second region that extend between the first subregion of the active region and the second subregion of the active region;
removing the first gate dielectric sublayer in the second region;
depositing a second gate dielectric sublayer in the first region and the second region to form the gate dielectric layer;
wherein a thickness of the gate dielectric layer in the first region is different from a thickness of the gate dielectric layer in the second region.

3. The method of claim 1, wherein the gate dielectric layer is formed by:
depositing an intermediate gate dielectric layer in a first region and a second region that extend between the first subregion of the active region and the second subregion of the active region;
removing a portion of the intermediate gate dielectric layer in the second region to form the gate dielectric layer, such that a thickness of the gate dielectric layer in the first region is different from a thickness of the gate dielectric layer in the second region.

4. The method of claim 1, wherein the gate dielectric layer is formed by:
forming a first gate dielectric sublayer in a first region that extends between the first subregion of the active region and the second subregion of the active region; and
forming a second gate dielectric sublayer in a second region that extends between the first subregion of the active region and the second subregion of the active region to form the gate dielectric layer;
wherein a dielectric constant of the first gate dielectric sublayer is different from a dielectric constant of the second gate dielectric sublayer.

5. The method of claim 1, wherein the gate structure comprises a first region and a second region;
wherein a work function of the first region is different from a work function of the second region.

6. The method of claim 1, further comprising, prior to forming the source/drain (S/D) regions, forming a first dielectric sidewall on one side of the gate structure that is located between the first subregion of the active region and the second subregion of the active region.

7. The method of claim 6, further comprising, prior to forming the source/drain (S/D) regions, forming a second dielectric sidewall adjacent the first dielectric sidewall, wherein the second dielectric sidewall extends across only a portion of the active region.

8. The method of claim 1, further comprising:
forming a first insulating layer over the substrate;
etching openings through the first insulating layer to the S/D electrodes and the gate structure; and
filling the openings with an electrically conductive material to form at least one source via, at least one drain via, and at least one gate via.

9. The method of claim 8, wherein the at least one gate via is located over the active region.

10. The method of claim 8, further comprising:
forming a second insulating layer over the first insulating layer;
etching the second insulating layer to form pads over the at least one source via, at least one drain via, and at least one gate via; and
filling the pads with an electrically conductive material to form a source terminal, a drain terminal, and a gate terminal.

11. A method for forming a transistor, comprising:
forming isolation regions in a substrate on opposite sides of an active region;
forming a gate dielectric layer between the isolation regions in the active region, and dividing the active region into a first subregion and a second subregion on opposite sides of the gate dielectric layer;
forming a gate structure over the gate dielectric layer, the gate structure comprising a first side adjacent to the first subregion of the active region and a second side adjacent to the second subregion of the active region; and
forming source/drain (S/D) regions in the first and second subregions of the active region on opposite sides of the gate structure;
wherein a channel length between the source region and the drain region changes along a width of the gate structure.

12. The method of claim 11, wherein the gate dielectric layer is formed by:
forming a first gate dielectric sublayer in a first region and a second region that extend between the first subregion of the active region and the second subregion of the active region;
removing the first gate dielectric sublayer in the second region;
forming a second gate dielectric sublayer in the first region and the second region to form the gate dielectric layer;
wherein a thickness of the gate dielectric layer in the first region is different from a thickness of the gate dielectric layer in the second region.

13. The method of claim 11, wherein the gate dielectric layer is formed by:
forming a first gate dielectric sublayer in a first region that extends between the first subregion of the active region and the second subregion of the active region; and
forming a second gate dielectric sublayer in a second region that extends between the first subregion of the active region and the second subregion of the active region to form the gate dielectric layer;
wherein a dielectric constant of the first gate dielectric sublayer is different from a dielectric constant of the second gate dielectric sublayer.

14. The method of claim 11, wherein the gate structure comprises a first region and a second region;
wherein a work function of the first region is different from a work function of the second region.

15. The method of claim 11, further comprising, prior to forming the source/drain (S/D) regions, forming a dielectric sidewall that extends across only a portion of the active region.

16. A transistor, comprising:
a drain region;
a source region; and
a gate structure between the drain region and the source region;
wherein a channel length between the source region and the drain region changes along a width of the gate structure.

17. The transistor of claim 16, wherein the first side of the gate structure includes at least one non-linear segment.

18. The transistor of claim 16, further comprising a gate dielectric layer having a first region and a second region that extend between the source region and the drain region, wherein a thickness of the first region is different from a thickness of the second region or wherein a dielectric constant of the first region is different from a dielectric constant of the second region.

19. The transistor of claim 16, wherein the gate structure has a first region and a second region that extend between the source region and the drain region, wherein a work function of the first region is different from a work function of the second region.

20. The transistor of claim 16, wherein the gate structure comprises a first end with a first gate length and a second end with a second gate length, wherein a difference between the first gate length and the second gate length is at least 0.5 nanometers.
